(19) United States
(12) Patent Application Publication
(10) Pub. No.: US 2007/0087291 A1
(43) Pub. Date: Apr. 19, 2007

(54) Lithography process to reduce interference

(75) Inventors: Tsai-Sheng Gau, Hsin Chu City (TW); Jaw-Jung Shin, Hsin Chu (TW); Chun-Kuang Chen, Taoyuan (TW); Jan-Wen You, Jhongli City (TW); Burn-Jeng Lin, Hsin Chu (TW)

Correspondence Address: TUNG & ASSOCIATES, Suite 120, 838 West Long Lake Road, Bloomfield Hills, MI, 48302, US

(73) Assignee: Taiwan Semiconductor Manufacturing Co., Ltd.

(21) Appl. No.: 11/252,499

(22) Filed: Oct. 18, 2005

(51) Int. Cl. G03F 7/20

(52) U.S. Cl. 430/311; 430/394

(57) ABSTRACT

A method and associated masks for carrying out a lithographic imaging process to reduce or avoid a strong interference effect in off-axis illumination, the method including providing a resist layer on a substrate; illuminating a first group of line patterns through a first mask on the resist layer; illuminating a second group of line patterns through a second mask on the resist layer, the second group of line patterns oriented nonparallel with respect to the first group of line patterns; and, developing the illuminated resist layer.

### FIELD OF THE INVENTION

This invention generally relates to lithography processes for use in circuitry patterning in a micro-integrated circuit manufacturing process and more particularly to a method and masks for use in exposing non-parallel oriented lines to avoid or reduce a strong interference effect.

### BACKGROUND OF THE INVENTION

In semiconductor device manufacturing, photolithography is typically used to transfer a pattern for forming semiconductor features onto a resist layer for subsequent etching of semiconductor device features (structures). During a photolithographic process, radiant energy such as ultraviolet light is passed through a photomask (mask), also referred to as a reticle, to expose a radiant energy sensitive material such as photoresist formed on the wafer process surface. The mask includes predetermined circuitry patterns and having attenuating regions and non-attenuating regions where the radiant energy is modulated in both intensity and phase. In a typical process, portions of a photoresist exposed through a mask are then developed to form a pattern for subsequent processes such as etching and underlying material layer according to the pattern to form semiconductor features.

As semiconductor device feature sizes have decreased to sizes smaller than the wavelength of light used in photolithographic processes, optical interference of wavefronts of light passing through the photomask, increasingly becomes a problem in forming features with small critical dimensions (CD's). Light passing through different portions of a photomask. causes constructive and destructive interference effects, also referred to as optical fringing or diffraction, which causes undesired light exposure variation on the photoresist in undesired places. As a result, a loss of pattern resolution and image contrast occurs in transferring the reticle pattern to the photoresist.

To enhance the resolution of a lithographic process, various approaches have been proposed, including improvements in the stepper, the photomask, and the photoresist. Off-axis illumination is one way to improve the resolution and contrast of a lithographic process without having to resort to other methods such as using shorter wavelengths of light. In off-axis illumination, beams of light are directed through the reticle such that the light strikes the projection lens at the edge of the entrance pupil, and subsequently strikes the mask at an angle of incidence referred to as off-axis. The angle of incidence of the off-axis light affects the transmission of diffraction orders of the diffracted light to advantageously affect light interference.

One off-axis illumination technique uses four beams (sources) of light projected through an aperture and is known as quadrupole or quasar illumination. One problem with quadrupole illumination is that improved imaging advantages have thus far been achieved only where all features (e.g., lines) are all aligned (oriented) in the same direction (e.g. parallel). If pattern features are aligned in different directions (non-parallel), a distortion of the transferred pattern occurs, for example creating ripples at the resist pattern feature edges, also referred to as the strong interference effect.

Thus, there is a need in the semiconductor manufacturing art for an improved method for off-axis illumination to allow improved lithography of semiconductor features including features that are aligned nonparallel to one another.

It is therefore among the objects of the present invention to provide an improved method for off-axis illumination to allow improved lithography of semiconductor features including features that are aligned nonparallel to one another, in addition to overcoming other shortcomings and deficiencies of the prior art.

### SUMMARY OF THE INVENTION

To achieve the foregoing and other objects, and in accordance with the purposes of the present invention, as embodied and broadly described herein, the present invention provides a method and associated masks for carrying out a lithographic imaging process to reduce or avoid a strong interference effect in off-axis illumination.

In a first embodiment, the method includes providing a resist layer on a substrate; illuminating a first group of line patterns through a first mask on the resist layer; illuminating a second group of line patterns through a second mask on the resist layer, the second group of line patterns oriented nonparallel with respect to the first group of line patterns; and, developing the illuminated resist layer.

These and other embodiments, aspects and features of the invention will be better understood from a detailed description of the preferred embodiments of the invention which are further described below in conjunction with the accompanying Figures.

### BRIEF DESCRIPTION OF THE DRAWINGS

FIG. 1 is a top planar view of a portion of a patterned resist surface according to an embodiment of the present invention.

FIGS. 2A and 2B are top planar views of portions of masks according to an embodiment of the present invention.

FIG. 3 is a process flow diagram including several embodiments of the present invention.

### DETAILED DESCRIPTION OF THE PREFERRED EMBODIMENTS

Although the method of the present invention is explained by reference to the formation of gate structure and associated conductive (e.g., polysilicon) lines, it will be appreciated that the method of the present invention may be applied to the formation of any semiconductor device feature or features where non-parallel lines defining the feature or features, e.g., are present to avoid or reduce undesired illumination interference effects in a lithographic exposure process. The method of the present invention may be applied to any off-axis illumination method, although it is particularly advantageous for quadrupole illumination, for example where the source light for a lithographic exposure step passes through an aperture having more than one opening (e.g., four openings) to illuminate a mask from an off-axis (e.g. non-perpendicular to the mask imaging surface) direction.

The method of the present invention includes carrying out at least two exposure (imaging) processes, each of which may include multiple illumination steps, through at least two respective masks where the respective imaging processes are illuminated with off-axis, preferably quadruple illumination. For example, a first mask includes a feature (e.g., line) having a first orientation and the second mask includes features (e.g., lines) oriented non-parallel with respect to the first orientation. The non-parallel orientations, may for example, form an angle between the first and second orientations of greater than about 0 degrees to about 90 degrees, e.g., including an angle of 45 degrees and/or 90 degrees (perpendicular). In an important aspect of the invention the second mask includes a light blocking portion, preferably larger than and surrounding (encompassing) the first feature to block illumination of a resist layer portion comprising a transferred image of the first feature. In addition, the respective first and second exposure (imaging) processes may be carried out in any order.

For example, it has been found that when off-axis quadrupole illumination is used, that undesired interference patterns (rippling effect), also referred to as the strong interference effect, are produced at the edges of patterned features where the patterned features include non-parallel orientation (e.g., lines) with respect to one another. It has also been found that by separately imaging a first feature portion having a first orientation using a first mask and imaging a second or subsequent feature portions (e.g., lines) including non-parallel oriented feature portions using a respective light (illumination) blocking mask portion to block light illumination with respect to previously imaged non-parallel feature portions e.g., the first feature portion, that the rippling effect caused by undesired light interference effects can be reduced or avoided.

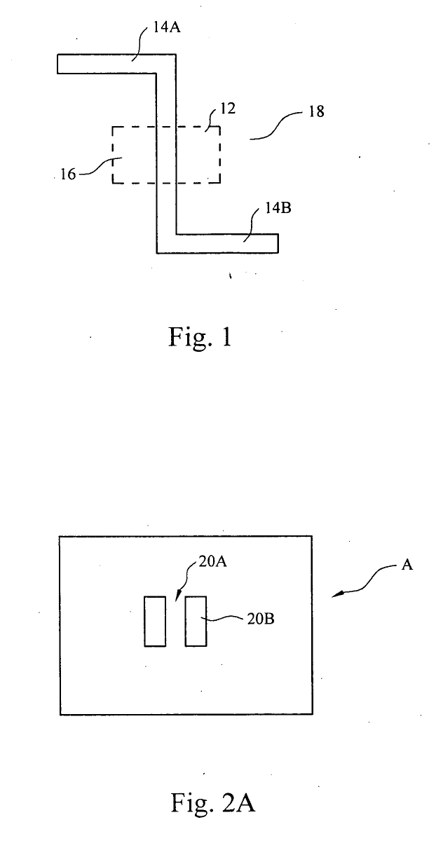

Referring to FIG. 1, in exemplary implementation of the present invention is shown a top planar view of an imaged and developed resist layer overlying a conductive material (e.g., polysilicon) layer e.g., 18. According to an exemplary aspect of the present invention, the patterned resist layer includes pattern features formed by two exposure processes through respective masks. It will be appreciated that a plurality of masks and associated exposure processes may be carried out. In an exemplary and preferred implementation, the patterned resist layer includes a gate electrode portion 12 and conductive (e.g., polysilicon) line portions 14A and 14B. The gate electrode portion 12 is disposed within an active area 16 of the semiconductor substrate (e.g., semiconductor wafer) shown in dotted outline of an area of the semiconductor substrate underlying the polysilicon layer e.g., 18. It will be appreciate that the resist portions cover an underlying layer, e.g. a polysilicon layer 18, for carrying out a subsequent conventional dry etching step according to the patterned resist portions to form polysilicon lines and a gate electrode structure. It will be appreciated that a hardmask (e.g., nitride) layer (not shown) may be provided over the polysilicon layer. The patterned resist portions e.g., gate electrode portion 12 and conductive (e.g., polysilicon) line portions 14A and 14B are shown following exposure and development of a resist layer according to preferred embodiment outlined below.

According to an important aspect of the invention, the patterned resist portion e.g., conductive line portions 14A and 14B and the gate electrode portion 12 are exposed with an off-axis axis illumination method in separate resist exposure steps using different respective masks for exposing the gate electrode portion and the conductive line portions. It will be appreciated that the gate electrode portion and the conductive line portions may be exposed in any order according to the present invention. Preferably the off-axis illumination method is a quadrupole source of light and may include any wavelength range such as I-line, G-line, and deep ultraviolet (DUV) including KrF (e.g., 248 nm) and ArF (e.g., 193 nm) light sources. It will be appreciated that the resist may be any positive resist such as I line, G line, or DUV resists.

In an important aspect of the invention, the gate electrode portion 12 of the resist including an adjacent surrounding area is protected from light exposure during an illumination step to image the conductive line portions 14A and 14B. A separate mask is used to define the gate electrode portion within the protected area.

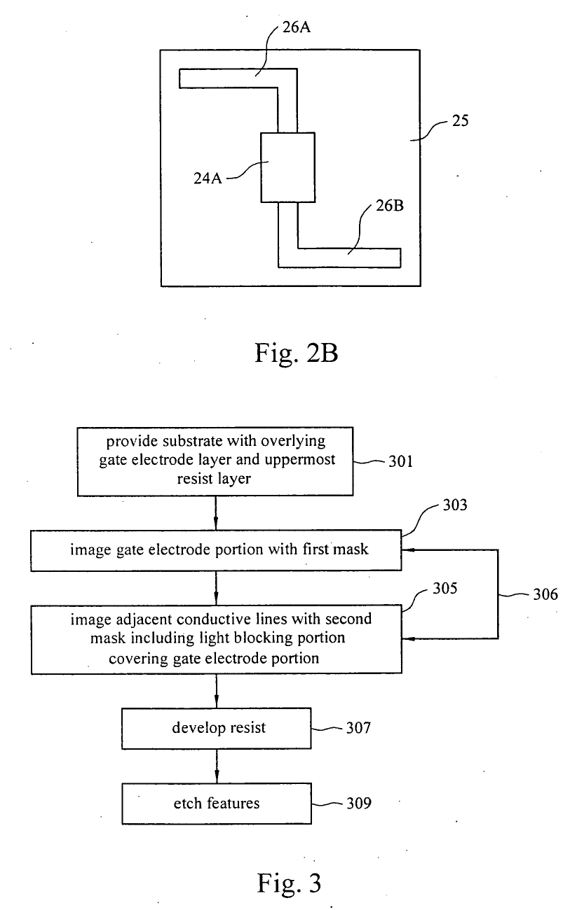

Referring to FIG. 2A is shown an exemplary mask A for exposing the gate electrode portion having opaque portions e.g., 20A defining a gate electrode portion, and transparent or semi-transparent portions e.g., 20B adjacent the gate electrode portion. Mask A may be a binary mask or an attenuating phase shift mask (PSM). In addition, it will be appreciated that more than one, e.g., a plurality of individual exposures (illuminations) may take place in an exposure process e.g., passing illumination through mask A to illuminate the resist. For example, multiple exposure through focus (FLEX) methods as are known in the art may be implemented. In addition, any conventional illumination method may be used including scanning methods, e.g., using a scanning projection aligner and stepping (step-and-repeat) methods e.g., using a reduction step-and-repeat projection aligner (stepper).

Referring to FIG. 2B is shown a top planar view of a portion of a second mask B used to expose the conductive line portions 14A and 14B. Mask B is preferably formed with an enlarged opaque portion 24A for encompassing the gate electrode portion 12 to protect an area of the gate electrode imaged area of the resist including a surrounding adjacent area from illumination. It will be appreciated that the conductive line portions of the mask e.g., 26A and 26B are also opaque while portion 25 is transparent or semi-transparent. The exposure process associated with mask B for imaging the conductive line portions preferably includes the same preferred embodiments as outlined above for the gate electrode imaging process.

Thus a method and associated masks for exposing features oriented non-parallel with respect to one another has been presented for improving contrast and resolution in a resist imaging process while avoiding or reducing a strong interference effect when using off-axis illumination such as quadrupole illumination. By carrying out multiple masking exposure steps where one masking step includes illumination of a first feature portion with a first orientation while separate masking and imaging steps include features oriented non-parallel with respect to the first orientation undesired illumination interference effects are avoided or reduced. In separate imaging steps using a second or subsequent mask for imaging the non-parallel second feature portions, portions of the mask include opaque portions for blocking illumination of the first feature portion thereby improving a resolution and/or contrast in a lithographic patterning process.

Referring to FIG. 3 is a process flow diagram including several embodiments of the present invention. In process 301, a substrate with an overlying gate electrode material layer and upper most resist layer is provided. In process 303, a first imaging process including off-axis illumination is carried out using a first mask to image a gate electrode portion. In process 305 a second imaging process using a second mask is carried out to image conductive lines where the conductive lines include portions non-parallel to the gate electrode portion and where the second mask includes an illumination blocking portion encompassing the gate electrode portion. The order of steps 303 and 305 may be reversed as indicated by bi-directional arrow 306. In process 307, a development process is carried out to complete the resist patterning process. In process 309 an etching process is carried out to etch features into the gate electrode material layer according to the patterned resist layer.

The preferred embodiments, aspects, and features of the invention having been described, it will be apparent to those skilled in the art that numerous variations, modifications, and substitutions may be made without departing from the spirit of the invention as disclosed and further claimed below.

What is claimed is:

1. A method for patterning non-parallel resist lines comprising the steps of:
providing a resist layer on a substrate;
illuminating a first group of line patterns through a first mask on the resist layer;
illuminating a second group of line patterns through a second mask on the resist layer, the second group of line patterns oriented nonparallel with respect to the first group of line patterns; and,
developing the illuminated resist layer.

2. The method of claim 1, wherein the first mask comprises an opaque portion for blocking illumination to an area on the resist layer comprising the second group of line patterns.

3. The method of claim 1, wherein the second group of line patterns comprises a gate pattern.

4. The method of claim 3, wherein the first group of line patterns is contiguous with a portion of the gate pattern.

5. The method of claim 1, wherein the steps of illuminating the first group and illuminating the second group comprises off-axis illumination.

6. The method of claim 5, wherein the off-axis illumination comprises quadrupole illumination.

7. The method of claim 1, wherein the second group of line patterns comprises lines forming an angle with respect to the first group of line patterns from greater than about 0 degrees to about 90 degrees.

8. The method of claim 1, wherein the first and second masks are selected from the group consisting of a binary mask and an attenuating phase shift mask.

9. The method of claim 1, wherein the step of illuminating the second group of line patterns is performed prior to the step of illuminating the group of line patterns.

10. The method of claim 1, wherein the steps of illuminating the first group and illuminating the second group comprises illumination methods selected from the group consisting of a scanning illumination and step and repeat illumination.

11. A method for patterning non-parallel resist lines comprising a gate electrode portion and conductive line portions comprising the steps of:
providing a resist layer on a substrate;
illuminating a conductive line pattern on the resist layer through a first mask;
illuminating a gate pattern on the resist layer through a second mask, the gate pattern oriented nonparallel with respect to the conductive line pattern; and,
developing the illuminated resist layer.

12. The method of claim 11, wherein the first mask further comprises an illumination blocking portion for blocking illumination to an area on the resist layer comprising the gate pattern.

13. The method of claim 11, wherein the conductive line pattern comprises portions oriented perpendicular to the gate pattern.

14. The method of claim 11, wherein the steps of illuminating a conductive line pattern and illuminating a gat pattern comprise off-axis illumination.

15. The method of claim 14, wherein the off-axis illumination comprises quadrupole illumination.

16. The method of claim 11, wherein the conductive line pattern comprises lines forming an angle with respect to the gate pattern from greater than about 0 degrees to about 90 degrees.

17. The method of claim 11, wherein the first and second masks are selected from the group consisting of a binary mask and an attenuating phase shift mask.

18. The method of claim 11, wherein the step of illuminating the gate pattern is carried out prior to the step of illuminating the conductive line pattern.

19. The method of claim 11, wherein the steps of illuminating a conductive line pattern and illuminating a gate pattern comprises illumination methods selected from the group consisting of a scanning illumination and step and repeat illumination.

20. A method for patterning non-parallel resist lines comprising a gate electrode portion and conductive line portions comprising the steps of:
providing a resist layer on a substrate;
illuminating a gate pattern on the resist layer through a first mask in a first exposure process comprising off-axis illumination;
illuminating a conductive line pattern on the resist layer through a second mask in a second exposure process comprising off-axis illumination, the conductive line pattern oriented nonparallel with respect to the gate pattern; and,
developing the illuminated resist layer.
